(19) United States
(12) Patent Application Publication
(10) Pub. No.: US 2017/0213949 A1
(43) Pub. Date: Jul. 27, 2017

(54) POWER GENERATOR FOR VEHICLE

(71) Applicant: TOYOTA JIDOSHA KABUSHIKI KAISHA, Toyota-shi (JP)

(72) Inventor: Kazuhiro SUGIMOTO, Susono-shi (JP)

(73) Assignee: TOYOTA JIDOSHA KABUSHIKI KAISHA, Toyota-shi (JP)

(21) Appl. No.: 15/412,333

(22) Filed: Jan. 23, 2017

(30) Foreign Application Priority Data
Jan. 25, 2016 (JP) 2016-011646

(51) Int. Cl. H01L 35/30; H01L 35/32

(52) U.S. Cl. CPC H01L 35/30; H01L 35/32

(57) ABSTRACT

A power generator includes thermoelectric transducers configured so that the band gap energy of an intrinsic semiconductor part disposed between an n-type semiconductor part and a p-type semiconductor part is lower than each band gap energy of the n-type semiconductor part and the p-type semiconductor part. The power generator includes a thermoelectric transducer module including a transducer stack formed by a plurality of thermoelectric transducers and a housing that houses the transducer stack. Each of the thermoelectric transducers of the thermoelectric transducer module is installed in an exhaust pipe in such a manner that an end face of the n-type semiconductor part or the p-type semiconductor part on a side opposite to the intrinsic semiconductor part is opposed to the flow of exhaust gas. A part of the housing on the upstream side of exhaust gas flow is a shield configured to cover the end face of each thermoelectric transducer.

### CROSS-REFERENCE TO RELATED APPLICATION

This application is based on and claims the benefit of Japanese Patent Application No. 2016-011646, filed on Jan. 25, 2016, which is incorporated by reference herein in its entirety.

### BACKGROUND

Technical Field

The present disclosure relates to a power generator for a vehicle, and more particularly to a power generator for a vehicle that incorporates a thermoelectric transducer.

Background Art

There are various thermoelectric transducers based on the Seebeck effect. For such a thermoelectric transducer to produce an electromotive voltage, there needs to be a temperature difference between the two kinds of metals or semiconductors forming the thermoelectric transducer. Thus, power generation using the thermoelectric transducer requires a device that maintains the temperature difference, such as a cooler. WO 2015125823 A1 discloses a semiconductor single crystal that can be used as a thermoelectric transducer capable of generating power without the temperature difference.

Specifically, the semiconductor single crystal disclosed in WO 2015125823 A1 includes an n-type semiconductor part, a p-type semiconductor part, and an intrinsic semiconductor part disposed between the n-type semiconductor part and the p-type semiconductor part, and the band gap energy of the intrinsic semiconductor part is set to be lower than each band gap energy of the n-type semiconductor part and the p-type semiconductor part. If the semiconductor single crystal having this configuration is heated to fall within a predetermined temperature range, electrons in the valence band of only the intrinsic semiconductor part located at a pn junction is excited into the conduction band, even if there is no temperature difference between the n-type semiconductor part and the p-type semiconductor part. The electrons excited into the conduction band moves to the n-type semiconductor part, which has a lower energy, and the holes formed in the valence band moves to the p-type semiconductor part, which has higher energy. As a result of these movements, the carriers (electron and holes) are unevenly distributed, and the semiconductor single crystal serves as a power generating material with the p-type semiconductor part serving as a positive electrode and the n-type semiconductor part serving as a negative electrode. The semiconductor single crystal having this configuration used as a thermoelectric transducer can generate electric power when the temperature of the thermoelectric transducer is within the predetermined temperature range, even if there is no temperature difference between the n-type semiconductor part and the p-type semiconductor part.

In addition to WO 2015125823 A1, JP 2004-011512A is a patent document which may be related to the present disclosure.

### SUMMARY

In order to effectively use the heat produced in a vehicle, such as an automobile, the semiconductor single crystal disclosed in WO 2015125823 A1 as a thermoelectric transducer can be installed in a fluid that flows through some kind of flow channel of the vehicle. The flow velocity or temperature of the fluid may transiently vary depending on a request from a driver of the vehicle or other various requests. When the flow velocity or temperature of the fluid transiently varies depending on a request from a driver or another request, heat transfer to each of the n-type semiconductor part, the p-type semiconductor part and the intrinsic semiconductor part is not uniform and, as a result, a temperature difference may be produced between these parts. If, as a result of the temperature difference as just described being produced, the temperature of the n-type semiconductor part 12a or the p-type semiconductor part 12b having a relatively higher band gap energy becomes higher than the temperature of the intrinsic semiconductor part, it becomes difficult to efficiently produce the electromotive voltage of the thermoelectric transducer having the configuration disclosed in WO 2015125823 A1. As a result, efficient power generation may be difficult to be achieved using this thermoelectric transducer.

The present disclosure has been made to address the problem described above, and an object of the present disclosure is to provide a power generator for a vehicle, which includes a thermoelectric transducer configured so that the band gap energy of an intrinsic semiconductor part disposed between an n-type semiconductor part and a p-type semiconductor part is lower than each band gap energy of the n-type semiconductor part and the p-type semiconductor part, and in which the thermoelectric transducer is installed in a flow channel of the vehicle in such a manner as to efficiently generate electric power.

A power generator for a vehicle according to the present disclosure includes a thermoelectric transducer including an n-type semiconductor part, a p-type semiconductor part, and an intrinsic semiconductor part disposed between the n-type semiconductor part and the p-type semiconductor part. A band gap energy of the intrinsic semiconductor part is lower than each band gap energy of the n-type semiconductor part and the p-type semiconductor part. The power generator is used in a vehicle that includes a flow channel in which a fluid that supplies heat to the thermoelectric transducer flows. The thermoelectric transducer is installed in the flow channel in such a manner that an end face of the n-type semiconductor part or the p-type semiconductor part on a side opposite to the intrinsic semiconductor part is opposed to a flow of the fluid. The power generator further includes a shield installed so as to cover the end face.

The shield may be configured to cover the end face in such a manner as to be in contact with the end face and configured to have a lower thermal conductivity than that of the thermoelectric transducer.

The thermoelectric transducer may include a first thermoelectric transducer and a second thermoelectric transducer that are installed parallel to the flow of the fluid. The shield may be installed so as to cover each of the end face of the first thermoelectric transducer and the end face of the second thermoelectric transducer. A space that serves as a part of the flow channel may be provided between the first thermoelectric transducer and the second thermoelectric transducer.

The thermoelectric transducer may include a plurality of thermoelectric transducers. The power generator may include the plurality of thermoelectric transducers in a form of a thermoelectric transducer module. The thermoelectric transducer module may include a transducer stack formed by the plurality of thermoelectric transducers electrically connected to each other and a housing that houses the transducer stack. At least the thermoelectric transducer located at an uppermost stream side in a flow direction of the fluid, of the plurality of thermoelectric transducers forming the transducer stack, may be installed in the flow channel in such a manner that the end face thereof is opposed to the flow of the fluid. The shield may be configured as a part of the housing located at an upper stream side relative to the transducer stack in the flow direction of the fluid. The shield may be configured to have a lower thermal conductivity than that of another part other than the part of the housing.

The thermoelectric transducer module may include a plurality of thermoelectric transducer modules. The housing may include a plurality of housings. The plurality of thermoelectric transducer modules may be installed parallel to the flow of the fluid. In each of the plurality of thermoelectric transducer modules, the shield may be configured as the part of the housing located at the upper stream side relative to the transducer stack in the flow direction of the fluid. A space that serves as a part of the flow channel may be provided between respective housings of the plurality of thermoelectric transducer modules.

The flow channel may be an inner channel of an exhaust pipe of an internal combustion engine mounted on the vehicle, and the fluid may be exhaust gas that flows in the exhaust pipe.

According to the power generator for a vehicle of the present disclosure, the thermoelectric transducer configured so that the band gap energy of the intrinsic semiconductor part disposed between the n-type semiconductor part and the p-type semiconductor part is lower than the band gap energy of the n-type semiconductor part and the p-type semiconductor part, and the thermoelectric transducer is installed in the flow channel in such a manner that the end face of the n-type semiconductor part or the p-type semiconductor part on a side opposite to the intrinsic semiconductor part is opposed to the flow of the fluid. Further, the shield is installed so as to cover the end face of the thermoelectric transducer installed in this kind of manner With this kind of shield, the fluid can be prevented from directly colliding with the end face of the thermoelectric transducer. The heat transfer from the fluid to the end face can thus be hard to be facilitated. As a result, a temperature difference is less likely to be produced in such a manner that the temperature of the n-type semiconductor part or the p-type semiconductor part having a relatively higher band gap energy is higher than the temperature of the intrinsic semiconductor part, and the thermoelectric transducer can efficiently produce the electromotive voltage. Thus, efficient power generation can be achieved.

### BRIEF DESCRIPTION OF THE DRAWINGS

FIG. 1 is a diagram showing an application example of a power generator for a vehicle according to a first embodiment of the present disclosure;

FIG. 2 is a schematic perspective view showing a configuration of each thermoelectric transducer of the power generator shown in FIG. 1;

FIGS. 3A and 3B are conceptual diagrams showing statuses of the band gap energy of the thermoelectric transducer shown in FIG. 2;

FIG. 4 is a graph showing a relation between an electromotive voltage and the temperature of the thermoelectric transducer;

FIG. 5 is a diagram for illustrating the orientation, which is used as a premise in the first embodiment, of each thermoelectric transducer with respect to a flow direction F of exhaust gas;

FIGS. 6A and 6B are views for explaining an issue on installing, as a thermoelectric transducer module, the plurality of thermoelectric transducers in the flow of the exhaust gas, while adopting a configuration shown in FIG. 5;

FIGS. 7A and 7B are diagrams for explaining a characteristic configuration which the thermoelectric transducer module shown in FIG. 1 includes;

FIG. 8 is a cross-sectional view of the thermoelectric transducer module that is cut along a line A-A shown in FIG. 7A;

FIGS. 9A and 9B are diagrams for explaining an issue when the number of thermoelectric transducers stacked are increased in order to ensure a high electromotive voltage;

FIGS. 10A and 10B are diagrams for explaining a configuration of a power generator according to a second embodiment of the present disclosure;

FIG. 11 is a diagram for explaining an example of a favorable configuration used when a thermoelectric transducer is installed in the flow of the exhaust gas without taking the form of the thermoelectric transducer module;

FIG. 12 illustrates a relation between a distance L from a reference position of the thermoelectric transducer (more specifically, an end face of an n-type semiconductor part) and the heat transfer coefficient between the exhaust gas and the thermoelectric transducer; and

FIG. 13 is a diagram for illustrating another manner of stacking of the thermoelectric transducers shown in FIG. 2.

### DETAILED DESCRIPTION

In the following, embodiments of the present disclosure will be described with reference to the drawings. In the drawings, the same reference numerals denote the same or similar components.

### First Embodiment

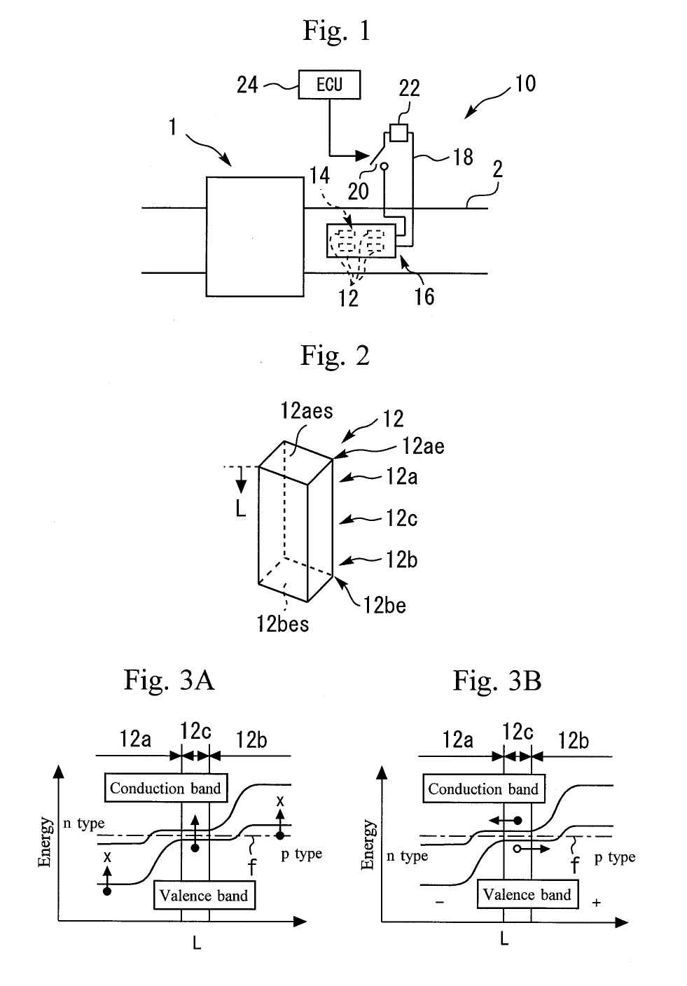

First, with reference to FIGS. 1 to 8, a first embodiment of the present disclosure will be described. FIG. 1 is a diagram showing an application example of a power generator 10 for a vehicle according to the first embodiment of the present disclosure. FIG. 2 is a schematic perspective view showing a configuration of each thermoelectric transducer 12 of the power generator 10 shown in FIG. 1.

### Installation Site of Power Generator in Vehicle

The installation site of heat transducers 12 which the power generator 10 according to the present embodiment includes is not particularly limited, as far as thermoelectric transducers 12 are installed in some kind of flow channel of the vehicle. In the first embodiment, as shown in FIG. 1, the thermoelectric transducers 12 are arranged, for example, in an exhaust pipe 2 of an internal combustion engine 1 that is mounted on the vehicle. In other words, in the example shown in FIG. 1, the heat of high-temperature exhaust gas after combustion in a combustion chamber of the internal combustion engine 1 is supplied to the thermoelectric transducers 12. Examples of a fluid that flows through a flow channel of the vehicle and supplies heat to the thermoelectric transducers 12 include not only the exhaust gas but also an engine cooling water that flows through a cooling water flow channel for cooling of the internal combustion engine 1, and an engine oil that flows through an oil flow channel for lubrication of the internal combustion engine 1.

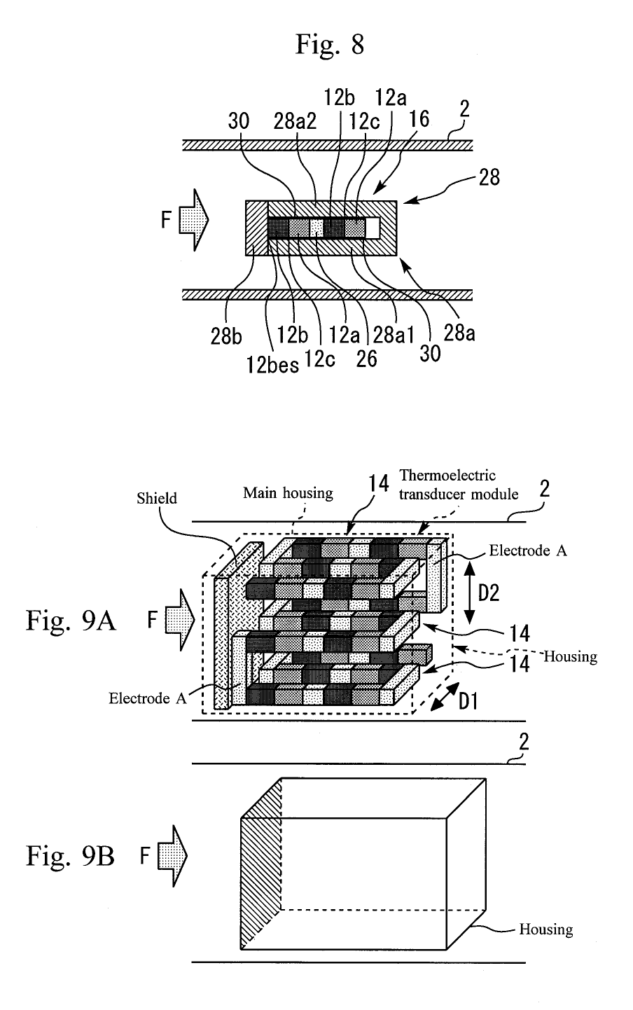

In the power generator 10 according to the present embodiment, the plurality of thermoelectric transducers 12 are installed in the exhaust gas in the form of a thermoelectric transducer module 16 with a transducer stack 14, which is formed by the plurality of thermoelectric transducers 12 electrically connected to each other. Details of the configuration of the thermoelectric transducer module will be described later with reference to FIG. 7A, FIG. 7B and FIG. 8. The power generator 10 is provided with an electrical circuit 18 that is configured to connect the opposite ends of the transducer stack 14 by conductive wires. The electrical circuit 18 is opened and closed with a switch 20. Electrical equipment (such as a light) 22 mounted on the vehicle is connected to the electrical circuit 18. The switch 20 is opened and closed under the control of an electronic control unit (ECU) 24 mounted on the vehicle.

With the power generator 10 configured as described above, during activation of the vehicle system, the transducer stack 14 is enabled to generate power by closing the switch 20 when the temperature of the thermoelectric transducers 12 reaches a temperature suitable for power generation as a result of heat from the exhaust gas being supplied to the thermoelectric transducers 12. In the present embodiment, the fluid for supplying heat is the exhaust gas, so that the exhaust heat of the internal combustion engine 1 can be recovered by the power generation. In addition, the electric power obtained by the power generation by the transducer stack 14 can be supplied to the electrical equipment 22. The switch 20 may be replaced with a variable resistor. In this example, the electric power supplied from the transducer stack 14 to the electrical equipment 22 can be controlled in more detail by adjusting the resistance of the variable resistor. Vehicle equipment that receives the electric power is not limited to the electrical equipment 22, and a battery that accumulates electric power may be connected to the electrical circuit 18 instead of or in addition to the electrical equipment 22, for example.

### Configuration of Thermoelectric Transducer

In the example shown in FIG. 2, the thermoelectric transducer 12 has the shape of a prism. The thermoelectric transducer 12 has an n-type semiconductor part 12a at one end and a p-type semiconductor part 12b at the other end. The thermoelectric transducer 12 further has an intrinsic semiconductor part 12c between the n-type semiconductor part 12a and the p-type semiconductor part 12b.

FIGS. 3A and 3B are conceptual diagrams showing statuses of the band gap energy of the thermoelectric transducer 12 shown in FIG. 2. In FIGS. 3A and 3B, the vertical axes indicate the energy of an electron, and the horizontal axes indicate the distance L (see FIG. 2) from an end face 12aes of the thermoelectric transducer 12 on the side of the n-type semiconductor part 12a.

As shown in FIGS. 3A and 3B, in the n-type semiconductor part 12a, the Fermi level f is in the conduction band, and in the p-type semiconductor part 12b, the Fermi level f is in the valence band. In the intrinsic semiconductor part 12c, the Fermi level f is at the middle of the forbidden band existing between the conduction band and the valence band. The band gap energy corresponds to the difference in energy between the uppermost part of the valence band and the lowermost part of the conduction band. As can be seen from these drawings, the band gap energy of the intrinsic semiconductor part 12c of the thermoelectric transducer 12 is lower than the band gap energies of the n-type semiconductor part 12a and the p-type semiconductor part 12b. Note that the length ratio between the n-type semiconductor part 12a, the p-type semiconductor part 12b and the intrinsic semiconductor part 12c shown in FIGS. 3A and 3B is just an example, and the ratio can vary depending on how the thermoelectric transducer (semiconductor single crystal) 12 is formed. The band gap energy of the n-type semiconductor part 12a, the p-type semiconductor part 12b and the intrinsic semiconductor part 12c can be measured in inverse photoelectron spectroscopy, for example.

The thermoelectric transducer (semiconductor single crystal) 12 having the characteristics described above (that is, the band gap energy of the intrinsic semiconductor part 12c is lower than the band gap energies of the n-type semiconductor part 12a and the p-type semiconductor part 12b) can be made of a clathrate compound (inclusion compound), for example. As an example of the clathrate compound, a silicon clathrate Ba₈Au₈Si₃₈ may be used.

The thermoelectric transducer 12 according to the present embodiment can be manufactured in any method, as far as the method can produce the thermoelectric transducer 12 having the characteristics described above. If the thermoelectric transducer 12 is made of, for example, the silicon clathrate Ba₈Au₈Si₃₈, the manufacturing method described in detail in International Publication No. WO 2015125823 A1 can be used, for example. The manufacturing method can be summarized as follows. That is, Ba powder, Au powder and Si powder are weighed in the ratio (molar ratio) of 8:8:38. The weighed powders are melted together by arc melting. The melt is then cooled to form an ingot of the silicon clathrate Ba₈Au₈Si₃₈. The ingot of the silicon clathrate Ba₈Au₈Si₃₈ prepared in this way is crushed into grains. The grains of the silicon clathrate Ba₈Au₈Si₃₈ are melted in a crucible in the Czochralski method, thereby forming a single crystal of the silicon clathrate Ba₈Au₈Si₃₈. The thermoelectric transducer 12 shown in FIG. 2 is provided by cutting the single crystal of the silicon clathrate Ba₈Au₈Si₃₈ prepared in this way into the shape of a prism (more specifically, the shape of a rectangular parallelepiped). The shape of the thermoelectric transducer is not limited to the rectangular parallelepiped, and the thermoelectric transducer may have any shape provided by cutting the single crystal into a desired shape, such as a cube or a column.

### Principle of Power Generation

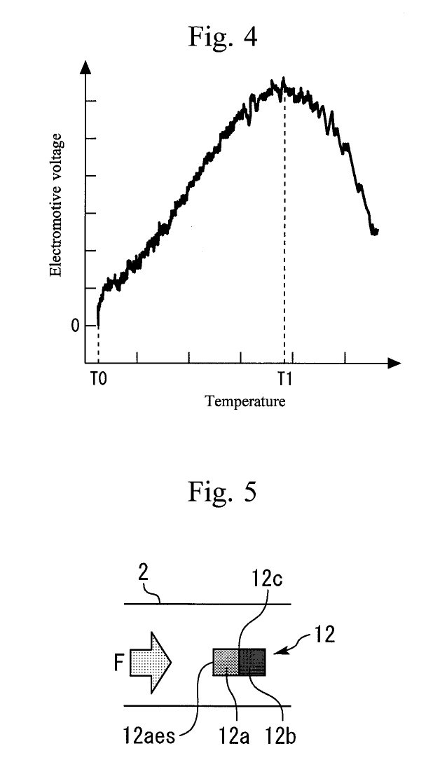

FIG. 3A is a conceptual diagram showing a status of thermal excitation of the thermoelectric transducer 12 when the thermoelectric transducer 12 is heated to a predetermined temperature. If the thermoelectric transducer 12 is heated to a temperature T0 (see FIG. 4 described later) or higher, electrons (shown by black dots) in the valence band are thermally excited into the conduction band, as shown in FIG. 3A. More specifically, if heat is supplied and energy exceeding the band gap energy is thereby supplied to an electron located in an uppermost part of the valence band, the electron is excited into the conduction band. In the process where the temperature of the thermoelectric transducer 12 increases, a condition can occur in which such thermal excitation of electrons occurs only in the intrinsic semiconductor part 12c, which has a relatively low band gap energy. FIG. 3A shows a status of the thermoelectric transducer 12 in which the thermoelectric transducer 12 is heated to a predetermined temperature (such as the temperature T0) that can allow such a condition to occur. In this status, no electrons are thermally excited in the n-type semiconductor part 12a and the p-type semiconductor part 12b, which have a relatively higher band gap energy.

FIG. 3B is a conceptual diagram showing movement of an electron (shown by the black dot) and a hole (shown by a white dot) when the thermoelectric transducer 12 is heated to the predetermined temperature described above. As shown in FIG. 3B, electrons excited into the conduction band move toward a part of lower energy, that is, toward the n-type semiconductor part 12a. On the other hand, holes formed in the valence band as a result of the electrons being excited move toward a part of higher energy, that is, toward the p-type semiconductor part 12b. The carriers are unevenly distributed in this way, so that the n-type semiconductor part 12a is negatively charged, and the p-type semiconductor part 12b is positively charged, and therefore, an electromotive force occurs between the n-type semiconductor part 12a and the p-type semiconductor part 12b. Thus, the thermoelectric transducer 12 can generate power even if there is no temperature difference between the n-type semiconductor part 12a and the p-type semiconductor part 12b. This principle of power generation differs from the Seebeck effect, which produces an electromotive force based on a temperature difference. The power generator 10 using the thermoelectric transducer 12 requires no temperature difference and therefore a cooling part that provides the temperature difference and therefore can be simplified in configuration.

FIG. 4 is a graph showing a relation between an electromotive voltage and the temperature of the thermoelectric transducer 12. The term “electromotive voltage” of the thermoelectric transducer 12 used herein refers to the potential difference between an end portion of the thermoelectric transducer 12 on the side of the p-type semiconductor part 12b serving as a positive electrode and an end portion of the thermoelectric transducer 12 on the side of the n-type semiconductor part 12a serving as a negative electrode. More specifically, the relation shown in FIG. 4 shows temperature characteristics of the electromotive voltage produced when the thermoelectric transducer 12 is heated in such a manner that no temperature difference is produced between the n-type semiconductor part 12a and the p-type semiconductor part 12b. Note that the temperature range in which the electromotive voltage is produced differs depending on the composition of the thermoelectric transducer.

As shown in FIG. 4, the electromotive voltage is produced when the thermoelectric transducer 12 is heated to the temperature TO or higher. More specifically, as the temperature of the thermoelectric transducer 12 increases, the electromotive voltage also increases. A possible reason why the electromotive voltage increases as the temperature increases as shown in FIG. 4 is that, as the amount of heat supplied increases, the number of electrons and holes that can be excited in the intrinsic semiconductor part 12c, which has a relatively low band gap energy, increases. As shown in FIG. 4, the electromotive voltage reaches a peak value at a certain temperature T1 and decreases as the thermoelectric transducer 12 is further heated beyond the temperature T1. A possible reason for this is that, as the temperature of the thermoelectric transducer 12 increases, not only electrons and holes in the intrinsic semiconductor part 12c but also electrons and holes in the n-type semiconductor part 12a and the p-type semiconductor part 12b are thermally excited.

### Method of Installing Thermoelectric Transducer With Respect to Direction of Flow of Exhaust Gas

As can be seen from FIG. 4 described above, power generation by using the thermoelectric transducer 12 is possible if the temperature of the thermoelectric transducer 12 falls within a predetermined range. More favorably, efficient power generation is possible if the temperature of the thermoelectric transducer 12 is close to the temperature T1 at which the peak electromotive voltage is achieved. Thus, to achieve efficient power generation using the their thermoelectric transducers 12 on the vehicle, a fluid, which can supply heat to the thermoelectric transducers 12 so that the temperature of each of the thermoelectric transducers 12 approaches a temperature suitable for power generation, is selected from among various flow channels of the vehicle, and the thermoelectric transducers 12 are installed in the selected fluid. More specifically, the temperature of the exhaust gas in the exhaust pipe 2 decreases as it flows downstream. When the exhaust gas is used as the fluid that serves as the heat source as in the present embodiment, the installation site of the thermoelectric transducer 12 in the exhaust pipe 2 along the direction of flow of the exhaust gas is determined so that a heat source that allows efficient power generation is provided.

### Issue with Efficient Power Generation

As described above, the thermoelectric transducer 12 is configured to produce an electromotive voltage as a result of the movement of electrons and holes caused by the electrons in the intrinsic semiconductor part 12c being thermally excited when the thermoelectric transducer 12 is supplied with heat from the fluid. To achieve efficient power generation using the thermoelectric transducers 12, it is required to take into consideration the following issue.

It can be said that, under a steady flow of heat in which the flow velocity and temperature of a fluid (in the present embodiment, exhaust gas) that serves as a heat source are steadily constant, the temperature of each part of the thermoelectric transducer 12 that is supplied with heat from the fluid approaches a constant value with lapse of time. However, the flow velocity or temperature of a fluid of the vehicle may transiently vary depending on a request from a driver of the vehicle or other various requests. When the flow velocity or temperature of the fluid transiently varies as just described, heat transfer to each part of the n-type semiconductor part 12a, the p-type semiconductor part 12b and the intrinsic semiconductor part 12c is not uniform and, as a result, a temperature difference may be produced between these parts. If a temperature difference is produced in the thermoelectric transducer 12 in such a manner that the temperature of the intrinsic semiconductor part 12c is higher than the temperature of the n-type semiconductor part 12a and the p-type semiconductor part 12b, thermal excitation of electrons in the intrinsic semiconductor part 12c is promoted compared with thermal excitation of electrons in the n-type semiconductor part 12a and the p-type semiconductor part 12b. This is favorable, rather than an issue. However, depending on the installation of the thermoelectric transducer 12 with respect to the fluid, a temperature difference may be likely to be produced in such a manner that the temperature of one or both of the n-type semiconductor part 12a and the p-type semiconductor part 12b is higher than the temperature of the intrinsic semiconductor part 12c. As the temperature difference in this manner increases, electrons are more easily thermally excited in the one or both of the n-type semiconductor part 12a and the p-type semiconductor part 12b. This may make it harder for the thermoelectric transducer 12 to produce the electromotive voltage. As a result, efficient power generation may be difficult to be achieved.

### Issue on Installing Thermoelectric Transducer in Orientation Used as Premise in First Embodiment

FIG. 5 is a diagram for illustrating the orientation, which is used as a premise in the first embodiment, of each thermoelectric transducer 12 with respect to the flow direction F of the exhaust gas. In FIG. 5 and other drawings, for the sake of clarity of the arrangement of the thermoelectric transducers 12, the n-type semiconductor part 12a and the p-type semiconductor part 12b of the thermoelectric transducer 12 are distinguished by color. The intrinsic semiconductor part 12c between the n-type semiconductor part 12a and the p-type semiconductor part 12b lies around the boundary between the parts 12a and 12b.

As shown in FIG. 5, in the present embodiment, each of the thermoelectric transducers 12 is installed inside the exhaust pipe 2 in such a manner that an end face 12aes of the n-type semiconductor part 12a is opposed to the flow of the exhaust gas. If this arrangement is adopted, the end face 12aes becomes easy to be warmed when the thermoelectric transducer 12 is subjected to the exhaust gas whose temperature is higher than that of the thermoelectric transducer 12 itself. This is because, in the periphery of the end face 12aes that is opposed to the exhaust gas, the turbulence (flow) of the exhaust gas is enhanced due to the collision of the exhaust gas to the end face 12aes, heat transfer from the exhaust gas to the thermoelectric transducer 12 is facilitated with an enhancement of this turbulence (flow). In addition, the end face 12aes is a part having the highest band gap energy. Therefore, if the thermoelectric transducer 12 is installed as shown in FIG. 5, a temperature difference in the unfavorable manner described above (that is, in the manner that the temperature of the n-type semiconductor part 12a is higher than that of the intrinsic semiconductor part 12c) is likely to be produced. As a result, it may become difficult to efficiently provide an electromotive voltage of the thermoelectric transducer. This kind of issue also applies to a configuration in which an end face 12bes of the p-type semiconductor part 12b is opposed to the flow of the exhaust gas instead of the end face 12aes of the n-type semiconductor part 12a.

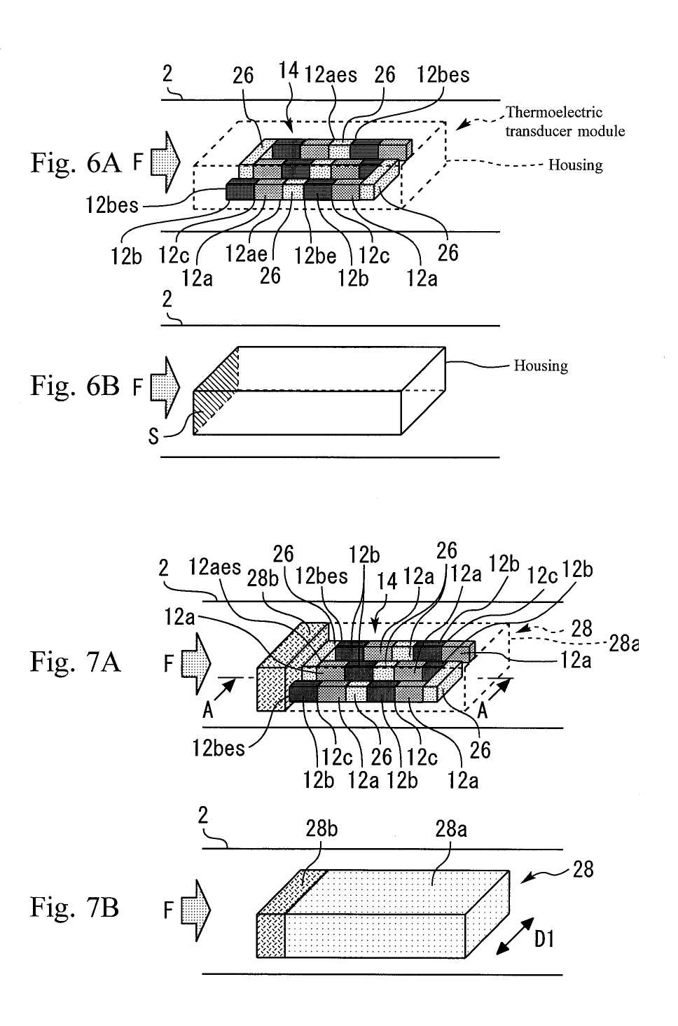

Next, FIGS. 6A and 6B are views for explaining an issue on installing, as a thermoelectric transducer module, the plurality of thermoelectric transducers 12 in the flow of the exhaust gas, while adopting a configuration shown in FIG. 5. A thermoelectric transducer module shown in FIG. 6A is referred to for comparison with the thermoelectric transducer module 16 according to the present embodiment. The structure of a transducer stack itself of the thermoelectric transducer module shown in FIG. 6A is the same as the transducer stack 14 of the thermoelectric transducer module 16.

The thermoelectric transducer module shown in FIG. 6A includes a housing that houses the transducer stack 14. As shown in FIG. 6A, the plurality of thermoelectric transducers 12 that form the transducer stack 14 are connected in series with each other with an electrode 26 interposed between adjacent thermoelectric transducers 12. That is, the transducer stack 14 includes the thermoelectric transducers 12 and the electrodes 26. More specifically, in the transducer stack 14, in order to ensure that the electric current smoothly flows while maximizing the potential difference between the opposite ends of the electrode 26, the electrode 26 is configured to connect an end portion 12ae (end face 12aes, for example) of the n-type semiconductor part 12a on the opposite side to the intrinsic semiconductor part 12c of one thermoelectric transducer 12 and an end portion 12be (end face 12bes, for example) of the p-type semiconductor part 12b on the opposite side to the intrinsic semiconductor part 12c of another thermoelectric transducer 12 to each other. In other words, the electrode 26 is configured to connect parts having the highest band gap energy to each other. Note that a portion including the end face 12aes of the n-type semiconductor part 12a and side surfaces of the n-type semiconductor part 12a in the vicinity of the end face 12aes is herein referred to as an “end portion 12ae”. Similarly, a portion including the end face 12bes of the p-type semiconductor part 12b and side surfaces of the p-type semiconductor part 12b in the vicinity of the end face 12bes is herein referred to as an “end portion 12be”.

As shown in FIG. 6A, some of the thermoelectric transducers 12 that forms the transducer stack 14 are installed in such a manner that the end face 12aes of the n-type semiconductor part 12a is oriented to the upstream side of the flow direction F of the exhaust gas, as with the configuration shown in FIG. 5. The rest of the thermoelectric transducers 12 are installed in such a manner that the end face 12bes of the p-type semiconductor part 12b is oriented to the upstream side of the flow direction F of the exhaust gas, that is, in an opposite manner with respect to the configuration shown in FIG. 5.

FIG. 6B schematically represents the outline of the housing shown in FIG. 6A. As shown in FIG. 6B, the exhaust gas collides with a surface S of the housing on the upstream side of the exhaust gas flow. As a result, the housing is easy to be warmed since heat conduction is facilitated at this surface S, due to the same reason as that described for the end face 12aes with reference to FIG. 5. Accordingly, if each of the thermoelectric transducers 12 forming the transducer stack 14 is installed in the housing in the orientation shown in FIG. 6A, there is the following issue.

Firstly, in the thermoelectric transducers 12 installed on the uppermost stream side of the exhaust gas flow, the end face 12aes and the end face 12bes that have the highest band gap energy are easy to be warmed. More specifically, in a row on the undermost side in FIG. 6A, the thermoelectric transducer 12 corresponds to the member located on the uppermost stream side of the exhaust gas flow. The end face 12bes of this thermoelectric transducer 12 that is in contact with the housing is easy to be warmed due to the heat conduction from the housing. On the other hand, in each of two rows on the upper side in FIG. 6A, the electrode 26 corresponds to the member located on the uppermost stream side of the exhaust gas flow. In addition, the thermal conductivity of the electrode 26 that is a metal is basically higher than that of the thermoelectric transducer 12. In other words, since the electrode 26 is easy to transfer heat, the end face 12aes and the end face 12bes that are connected to the electrode 26 are easy to be warmed due to the heat conduction from the housing through the electrode 26 even if the electrode 26 is located on the uppermost stream side. Because of this, in the thermoelectric transducers 12 of the transducer stack 14 that are located on the uppermost stream side of the exhaust gas flow, a temperature difference in the unfavorable manner described above is likely to be produced.

Moreover, in the process in which the temperature of the housing is increasing as a result of the heat being supplied from the exhaust gas, the temperature of the housing becomes the highest in the vicinity of the surface S at which the heat transfer coefficient is high, and decreases as the exhaust gas flows downstream. Therefore, if the transducer stack 14 is installed in the housing with the configuration shown in FIG. 6A, a temperature difference in the unfavorable manner described above is likely to be produced similarly at the thermoelectric transducers 12 other than the thermoelectric transducers 12 located on the uppermost stream side.

### Countermeasures for Installation Method of Thermoelectric Transducer According to First Embodiment

FIGS. 7A and 7B are diagrams for explaining a characteristic configuration which the thermoelectric transducer module 16 shown in FIG. 1 includes. FIG. 8 is a cross-sectional view of the thermoelectric transducer module 16 that is cut along a line A-A shown in FIG. 7A.

The thermoelectric transducer module 16 according to the present embodiment includes the transducer stack 14 and a housing that houses the transducer stack 14. In the power generator 10, the thermoelectric transducer module 16 having this kind of configuration is installed in the flow of the exhaust gas. More specifically, as shown in FIG. 7A, each of the thermoelectric transducers 12 that forms the transducer stack 14 are installed in the housing 28 with the orientation used as a premise in the present embodiment (more specifically, the orientation with which the end face 12aes or the end face 12bes is opposed to the flow of the exhaust gas).

Note that the way of stacking of the thermoelectric transducers 12 is not particularly limited. In the transducer stack 14, the thermoelectric transducers 12 are stacked in series with each other in such a way that, as shown in FIG. 7A, a plurality of thermoelectric transducers 12 are folded, for example, in a serpentine form with each other with the electrode 26 interposed between adjacent thermoelectric transducers 12. With the transducer stack 14, by appropriately determining the number of thermoelectric transducers 12 stacked, any desired level of electromotive voltage can be produced under the temperature condition of the thermoelectric transducers 12 expected from the heat supply from the exhaust pipe 2.

The housing 28 is formed so as to surround the transducer stack 14. As shown in FIG. 7B and FIG. 8, the housing 28 includes a main housing 28a and a shield 28b. The main housing 28a houses the transducer stack 14, and one end of the main housing 28a is open. The shield 28b is combined with this open end of the main housing 28a. The open end is obstructed by the shield 28b. When the thermoelectric transducer module 16 is installed in the flow of the exhaust gas, the shield 28b corresponds to a part of the housing 28 that is located on the upper stream side relative to the transducer stack 14 in the flow direction F of the exhaust gas. In addition to this, the housing 28 has the shape of a rectangular parallelepiped and is oriented in the exhaust pipe 2 so as to extend longwise along the flow direction F of the exhaust gas.

The shield 28b is configured to have a lower thermal conductivity than those of both of the thermoelectric transducer 12 and the main housing 28a. Specifically, the shield 28b may be made of a ceramic material, for example. That is, the shield 28b according to the present embodiment serve as a heat insulator. The main housing 28a may be favorably made of a material having a high thermal conductivity, and a metal, such as aluminum, can be used as the main housing 28a. Note that the material of the shield 28b is not limited to ceramics, and various metals, for example, may be used as far as the requirement is met that the thermal conductivity of the shield 28b is lower than that of the main housing 28a. Alternatively, the shield 28b may be configured to have a static air layer thereinside. Note that the housing 28 is fixed to the exhaust pipe 2 with an attachment not shown in the drawing.

Furthermore, inside the housing 28, the thermoelectric transducer 12 located on the uppermost stream side of the exhaust gas flow at a row (that is, row on the undermost side in FIG. 7A) is installed in such a manner that the end face 12bes of the p-type semiconductor part 12b is in contact with the shield 28b. In other words, with respect to the thermoelectric transducer 12 located on the uppermost stream side, the shield 28b is installed so as to cover the end face 12bes of the p-type semiconductor part 12b with the manner as just described. On the other hand, in the remaining two rows (that is, two rows in each of two rows on the upper side in FIG. 7A), the end face 12aes or the end face 12bes of the two thermoelectric transducers 12 located on the uppermost stream side of the exhaust gas flow is not directly in contact with the shield 28b and in contact with the shield 28b with the electrode 26 interposed between the shield 28b and each of the thermoelectric transducers 12. In other words, with respect to these two thermoelectric transducers 12, the shield 28b is installed so as to cover the end face 12aes of the n-type semiconductor part 12a or the end face 12bes of the p-type semiconductor part 12b with the manner as just described. In addition, with respect to each of the thermoelectric transducers 12 other than the thermoelectric transducers 12 located on the uppermost upstream side, the end face 12aes or the end face 12bes that is opposed to the flow of the exhaust gas is covered by the shield 28b with the thermoelectric transducer 12 interposed between the shield 28b and each of the thermoelectric transducers 12 other than the thermoelectric transducers 12 located on the uppermost upstream side.

According to the thermoelectric transducer module 16 having the configuration described so far, in the transducer stack 14 that adopts the installation method by which the end face 12aes or the end face 12bes of each of the thermoelectric transducers 12 is opposed to the flow of the exhaust gas, a part of the housing 28 that is opposed to the flow of the exhaust gas (that is, a part on the upstream side) is configured as the shield 28b. Thus, in the housing 28 of the present configuration, a part at which heat convection is facilitated due to the collision of the exhaust gas corresponds to the shield 28b. Moreover, the shield 28b is made of a material having the low thermal conductivity. Because of this, an intensive (biased) increase in temperature at the part of the housing 28 on the upstream side can be reduced. As a result, a temperature difference in the unfavorable manner as already described is less likely to be produced in each of the thermoelectric transducers 12 in the housing 28, and each of the thermoelectric transducers 12 can efficiently produce the electromotive voltage. Accordingly, even if the flow velocity or the temperature of the exhaust gas which is the heat source transiently varies depending on, for example, a request from a driver of the vehicle, efficient power generation can be achieved using this thermoelectric transducer 12.

Moreover, the main housing 28a located on the downstream side of the shield 28b is configured with a material having a higher thermal conductivity than that of the shield 28b. This allows an intensive heat input to a part of the housing 28 to be reduced by the shield 28b and also allows the supply of the heat that is transferred from the exhaust gas to the main housing 28a through the outer surface of the main housing 28a to be facilitated with respect to each of the thermoelectric transducers 12. In addition, since the thermal conductivity of the main housing 28a is made higher, variation of the temperature of each part of the main housing 28a can be reduced when heat is supplied. As a result, variation of heat input to the each of the thermoelectric transducers 12 can be effectively reduced.

### Favorable Configuration on Heat Conduction to Each Thermoelectric Transducer from Main Housing

As describe below, the thermoelectric transducer module 16 according to the present embodiment has a favorable configuration on the heat conduction to each of the thermoelectric transducers 12 from the main housing 28a. More specifically, as shown in FIG. 8, the main housing 28a includes a pair of walls 28a1 and 28a2 that form two faces having a relatively large area in all faces forming the housing 28. As shown in FIG. 7B, the pair of walls 28a1 and 28a2 extend in a plate shape along the flow direction F of the exhaust gas and the perpendicular direction D1 that is perpendicular to the flow direction F when the thermoelectric transducer module 16 is installed in the exhaust pipe 2. One side surface of the transducer stack 14 is arranged facing an inner surface of the wall 28a1 with an insulator 30 interposed between the one side surface and the inner surface. The remaining wall 28a2 has an inner surface that is opposed to the inner surface of the wall 28a1. In the transducer stack 14, a side surface opposite to the above-described one side surface on a side of the wall 28a1 is arranged facing the wall 28a2 with an insulator 30 interposed between the side surface and an inner surface of the wall 28a2.

According to the above-described structure, the heat from the exhaust gas is transferred to the transducer stack 14 via the main housing 28a and insulator 30. More specifically, each of the thermoelectric transducers 12 that forms the transducer stack 14 is supplied with heat from the inner surface of the one wall 28a1 via the insulator 30, and also supplied with heat from the inner surface of the wall 28a2. In more detail, in each of the thermoelectric transducers 12, the intrinsic semiconductor part 12c is arranged so as to be in contact with surfaces of the respective insulators 30 for conducting the heat from the walls 28a1 and 28a2 of the main housing 28a. Therefore, according to the structure, the transducer stack 14 can be housed in the housing 28 in such a way that heat input to the intrinsic semiconductor part 12c can be effectively ensured.

In the first embodiment, there is described the example in which, with respect to the thermoelectric transducer 12 located on the uppermost side of the exhaust gas flow in the row on the undermost side in FIG. 7A, the thermoelectric transducer 12, the end face 12bes of the p-type semiconductor part 12b is in contact with the shield 28b. However, the end face 12aes or the end face 12bes of each of the thermoelectric transducers 12 housed in the housing 28 may be installed in such a manner as not to be in contact with the shield 28b. In addition, in this manner, the thermal conductivity of the shield 28b is not necessarily required to be lower than that of the thermoelectric transducer 12, as far as it is lower than that of the main housing 28a.

Furthermore, in the first embodiment, which has been described above, all the thermoelectric transducers 12 that forms the transducer stack 14 are installed in the exhaust pipe 2 in such a manner that, as an example, the respective end faces 12aes or 12bes are opposed to the flow of the exhaust gas. However, in a transducer stack housed in a housing of a thermoelectric transducer module according to the present disclosure, the benefit of installing the shield can be enjoyed (that is, an intensive (biased) increase in temperature at the part of the housing on the upstream side can be reduced and, as a result, a temperature difference in the unfavorable manner as already described is less likely to be produced), as far as one or more thermoelectric transducers located at least on the uppermost stream side of the flow direction of a fluid are installed in the manner described above. Accordingly, one or a plurality of thermoelectric transducers other than one or more thermoelectric transducers on the located on the uppermost stream side of the flow direction of a fluid may be installed with any desired orientation other than the manner described above.

### Second Embodiment

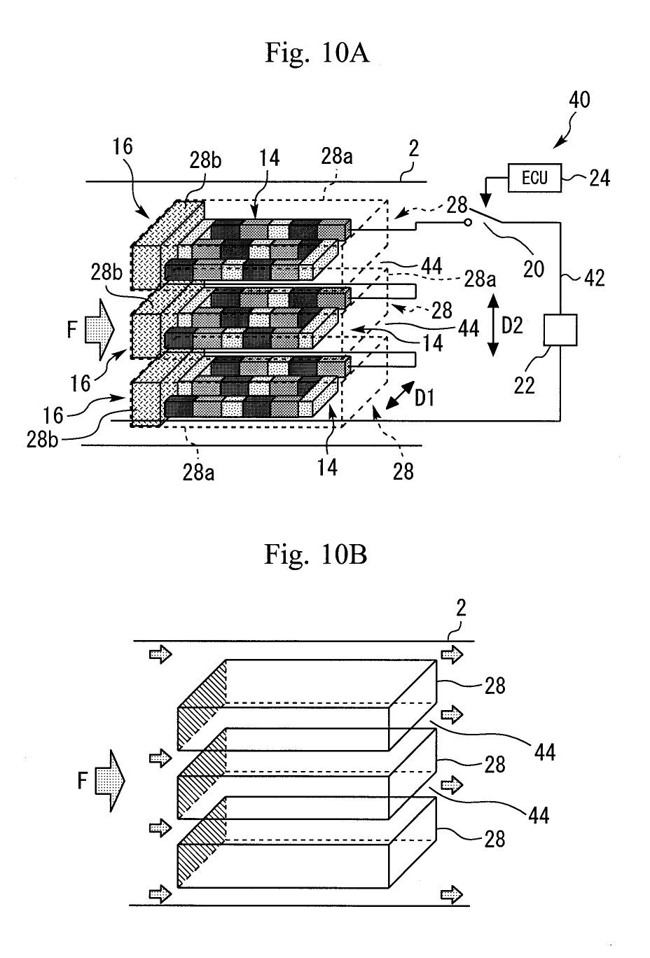

Next, with reference to FIGS. 9 and 10, a second embodiment of the present disclosure will be described.

The present embodiment is also directed to a configuration in which the thermoelectric transducers are installed in a fluid (as an example, exhaust gas) in the form of a thermoelectric transducer module, as in the first embodiment. FIGS. 9A and 9B are diagrams for explaining an issue when the number of thermoelectric transducers 12 stacked are increased in order to ensure a high electromotive voltage. The configuration shown in FIG. 9A corresponds to one in which three transducer stacks 14 are stacked with the respective electrode A interposed between adjacent transducer stacks 14. More specifically, it can be said that this configuration corresponds to one in which the thermoelectric transducers 12 are stacked in such a manner as to extend, using a plurality of transducer stacks 14 stacked so as to extend along both of the flow direction F of the exhaust gas and its perpendicular direction D1 that is perpendicular to the flow direction F, along the perpendicular direction D2 that is perpendicular to both of flow direction F and the perpendicular direction D1.

The thermoelectric transducer module shown in FIG. 9A corresponds to one in which a complex of the transducer stacks 14 having the configuration described above is housed in a housing. In the example of this thermoelectric transducer module, an intensive heat input to a part of a housing thereof on the upstream side of the flow direction F of the exhaust gas can also be reduced by configuring this part as a shield that is similar to the shield 28b according to the first embodiment. However, in the housing, the heat is input to each of the thermoelectric transducers 12 through a main housing. As a result, it is difficult to supply heat to the thermoelectric transducers 12 located at the middle of the complex.

FIGS. 10A and 10B are diagrams for explaining a configuration of a power generator 40 according to the second embodiment of the present disclosure. As shown in FIG. 10A, in the power generator 40 according to the present embodiment, a plurality of (as an example, three) thermoelectric transducer modules 16 are installed parallel to the flow of the exhaust gas. More specifically, in this example, each of the thermoelectric transducers 12 in the housing 28 of each of the thermoelectric transducer modules 16 is not stacked so as to extend three-dimensionally and is stacked so as to extend on a plane instead. Further, the three thermoelectric transducer modules 16 are connected to each other in series in an electric circuit 42. In the housing 28 of each of the thermoelectric transducer modules 16, a part of the housing 28 on the upstream side relative to the transducer stack 14 in the flow direction F of the exhaust gas is configured with the shield 28b. Furthermore, each of the thermoelectric transducer modules 16 having the shape of a rectangular parallelepiped is oriented so as to extend longwise along the flow direction F of the exhaust gas.

On that basis, as shown in FIGS. 10A and 10B, spaces 44 that each serve as a part of a flow channel of the exhaust pipe 2 are each provided between the respective housings 28 of adjacent ones of the three thermoelectric transducer modules 16.

According to the configuration described so far that includes the spaces 44, heat can be supplied to each of the thermoelectric transducers 12 in each of the thermoelectric transducer modules 16 from a greater number of directions as compared with the configuration shown in FIG. 9A. As a result, heat can be inputted more surely to each of the thermoelectric transducers 12 of each of the thermoelectric transducer modules 16. As just described, according to the present embodiment, where a plurality of thermoelectric transducers 12 are installed so as to extend three dimensionally in order to ensure a high electromotive voltage, a configuration that enables to input heat to each of the thermoelectric transducers 12 more surely can be realized. In addition, according to the present configuration, as can be seen from the comparison between FIG. 9B and FIG. 10B, a flow channel cross-sectional area that is obstructed by the thermoelectric transducer modules can also be reduced as compared with the configuration shown in FIG. 9A when an equal number of thermoelectric transducers 12 are installed. Therefore, the pressure loss of the exhaust pipe 2 can also be reduced.

Note that, in the above described second embodiment, with respect to two adjacent thermoelectric transducer modules 16 installed parallel to the flow of the exhaust gas with the space 44 interposed therebetween, any one of the thermoelectric transducers 12 of one thermoelectric transducer module 16 corresponds to a “first thermoelectric transducer” according to the present disclosure, and any one of the thermoelectric transducers 12 of the other thermoelectric transducer module 16 corresponds to a “second thermoelectric transducer” according to the present disclosure.

### Other Embodiments

In the first and second embodiments described above, the power generator 10 or 40 is provided with the transducer stack 14 formed by a plurality of thermoelectric transducers 12. However, the present disclosure is not necessarily limited to the power generators including, in the form of a thermoelectric transducer module, a plurality of thermoelectric transducers housed in a housing. More specifically, the power generator according to the present disclosure may include one or a plurality of thermoelectric transducers that are installed in a flow channel in such a manner that, without taking the form of the thermoelectric transducer module, an end face of the n-type semiconductor part or the p-type semiconductor part on a side opposite to the intrinsic semiconductor part is opposed to a flow of a fluid.

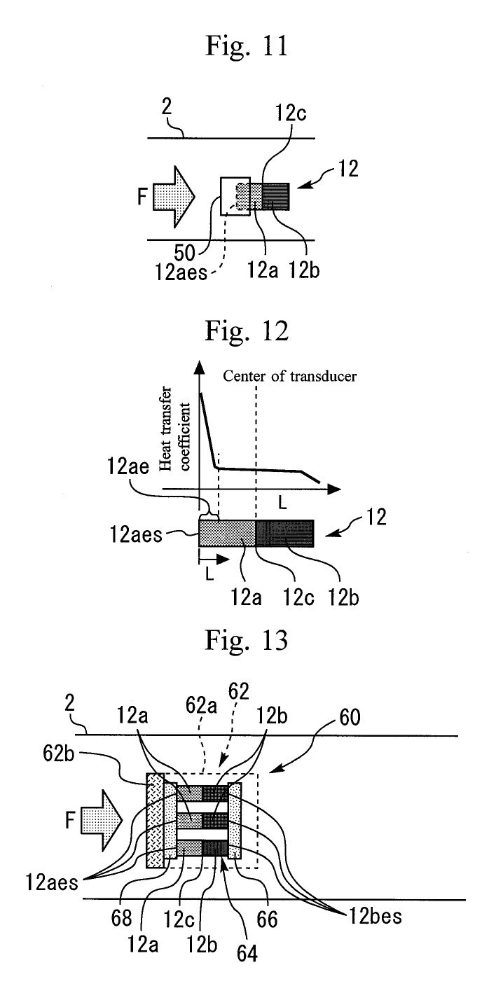

FIG. 11 is a diagram for explaining an example of a favorable configuration used when a thermoelectric transducer 12 is installed in the flow of the exhaust gas without taking the form of the thermoelectric transducer module. In the configuration shown in FIG. 11, one thermoelectric transducer 12 is installed in the flow of the exhaust gas in such a manner that the end face 12aes of the n-type semiconductor part 12a is opposed to the flow of the exhaust gas. Further, in this configuration, a shield 50 is installed to as to cover not only the end face 12aes but also the whole of the end portion 12ae of the n-type semiconductor part 12a. More specifically, the shield 50 is installed so as to cover the end portion 12ae in such a manner as to be in contact with the end portion 12ae. In addition, the shield 50 is configured to include a member (for example, ceramics) having a lower thermal conductivity than that of the thermoelectric transducer 12 and to serve as an insulator.

FIG. 12 illustrates a relation between the distance L from a reference position of the thermoelectric transducer 12 (more specifically, the end face 12aes of the n-type semiconductor part 12a) and the heat transfer coefficient between the exhaust gas and the thermoelectric transducer 12. As shown in FIG. 12, the heat transfer coefficient becomes relatively higher at the end portion 12ae of the n-type semiconductor part 12a including the end face 12aes with which the exhaust gas collides. In this end portion 12ae, the heat transfer coefficient becomes the highest at the end face 12aes and decreases as the distance L increases. Because of this, according to the present configuration which includes the shield 50 configured so as to cover the whole of the end portion 12ae, the exhaust gas can be prevented from directly colliding with the end portion 12ae (that is, a portion having the highest band gap energy). Therefore, an intensive heat input to the end portion 12ae can be reduced favorably. In addition, since the shield 50 is configured to serve as an insulator, the heat conduction from the shield 50 to the end portion 12ae can also be reduced. Accordingly, the present configuration can also successfully reduce an occurrence of a temperature difference in the unfavorable manner as already described.

Note that the shield 50 may be installed in such a manner as not to be in contact with the end face 12aes, as far as the shield 50 is configured so as to cover at least end face 12aes of the end portion 12ae. Since the exhaust gas can be prevented from directly colliding with the end face 12aes even if the shield 50 is installed as just described, an intensive heat input to the end face 12aes can be reduced. Further, if the shield 50 is installed in such a manner as not to be in contact with the end face 12aes, the thermal conductivity of the shield 50 is not necessarily required to be lower than that of the thermoelectric transducer 12.

Moreover, the number of thermoelectric transducers 12 that are an object of the configuration shown in FIG. 11 is not limited to one, and, at a location on the downstream side of the thermoelectric transducer 12 shown in FIG. 11, another plurality of thermoelectric transducers 12 located with the same orientation as that of the thermoelectric transducer 12 shown in FIG. 11 may be installed, as well as the thermoelectric transducer 12 shown in FIG. 11, in series with the shape of a rod with the electrode 26 interposed between adjacent thermoelectric transducers 12. In addition, the configuration shown in FIG. 11 can also similarly apply to an example in which the thermoelectric transducers 12 are installed in the flow of the exhaust gas in such a manner that the end face 12bes of the p-type semiconductor part 12b is opposed to the flow of the exhaust gas.

Next, FIG. 13 is a diagram for illustrating another manner of stacking of the thermoelectric transducers 12 shown in FIG. 2. A thermoelectric transducer module 60 shown in FIG. 13 includes a transducer stack 64 that is housed in a main housing 62a of a housing 62. Each of the thermoelectric transducers 12 that forms the transducer stack 64 is arranged in the housing 62 in such a manner that the end face 12aes of the n-type semiconductor part 12a is opposed to the flow of the exhaust gas. In addition, in this arrangement, a part of the housing 62 on the upstream side relative to the transducer stack 64 in the flow direction F of the exhaust gas is configured as a shield 62b, as with the thermoelectric transducer module 16 according to the first embodiment. Further, the shield 62b is configured to have a lower thermal conductivity than those of both of the thermoelectric transducer 12 and the main housing 62a, as in the first embodiment.

In the configuration shown in FIG. 13, end faces 12bes of the p-type semiconductor parts 12b serving as a positive electrode are electrically connected to each other by an electrode 66, and end faces 12aes of the n-type semiconductor part 12a serving as a negative electrode are electrically connected to each other by an electrode 68. The transducer stack of a plurality of thermoelectric transducers 12 is not limited to the stack including the thermoelectric transducers 12 connected in series with each other, such as those in the examples described above, and a stack including the thermoelectric transducers 12 connected in parallel with each other, such as the configuration shown in FIG. 13, is also possible. In addition, if a plurality of thermoelectric transducers 12 are stacked, a series connection of a plurality of thermoelectric transducers and a parallel connection of a plurality of thermoelectric transducers may be combined.

The embodiments and modifications described above may be combined in other ways than those explicitly described above as required and may be modified in various ways without departing from the scope of the present disclosure.

What is claimed is:

1. A power generator for a vehicle, comprising:
a thermoelectric transducer including an n-type semiconductor part, a p-type semiconductor part, and an intrinsic semiconductor part disposed between the n-type semiconductor part and the p-type semiconductor part, a band gap energy of the intrinsic semiconductor part being lower than each band gap energy of the n-type semiconductor part and the p-type semiconductor part,
wherein the power generator is used in a vehicle that includes a flow channel in which a fluid that supplies heat to the thermoelectric transducer flows,
wherein the thermoelectric transducer is installed in the flow channel in such a manner that an end face of the n-type semiconductor part or the p-type semiconductor part on a side opposite to the intrinsic semiconductor part is opposed to a flow of the fluid, and
wherein the power generator further comprises a shield installed so as to cover the end face.

2. The power generator for a vehicle according to claim 1,
wherein the shield is configured to cover the end face in such a manner as to be in contact with the end face and configured to have a lower thermal conductivity than that of the thermoelectric transducer.

3. The power generator for a vehicle according to claim 2,
wherein the thermoelectric transducer includes a first thermoelectric transducer and a second thermoelectric transducer that are installed parallel to the flow of the fluid,
wherein the shield is installed so as to cover each of the end face of the first thermoelectric transducer and the end face of the second thermoelectric transducer, and
wherein a space that serves as a part of the flow channel is provided between the first thermoelectric transducer and the second thermoelectric transducer.

4. The power generator for a vehicle according to claim 1,
wherein the thermoelectric transducer includes a plurality of thermoelectric transducers,
wherein the power generator comprises the plurality of thermoelectric transducers in a form of a thermoelectric transducer module,
wherein the thermoelectric transducer module includes a transducer stack formed by the plurality of thermoelectric transducers electrically connected to each other and a housing that houses the transducer stack,
wherein at least the thermoelectric transducer located at an uppermost stream side in a flow direction of the fluid, of the plurality of thermoelectric transducers forming the transducer stack, is installed in the flow channel in such a manner that the end face thereof is opposed to the flow of the fluid,
wherein the shield is configured as a part of the housing located at an upper stream side relative to the transducer stack in the flow direction of the fluid, and
wherein the shield is configured to have a lower thermal conductivity than that of another part other than the part of the housing.

5. The power generator for a vehicle according to claim 4,
wherein the thermoelectric transducer module includes a plurality of thermoelectric transducer modules,
wherein the housing includes a plurality of housings,
wherein the plurality of thermoelectric transducer modules are installed parallel to the flow of the fluid,
wherein, in each of the plurality of thermoelectric transducer modules, the shield is configured as the part of the housing located at the upper stream side relative to the transducer stack in the flow direction of the fluid, and
wherein a space that serves as a part of the flow channel is provided between respective housings of the plurality of thermoelectric transducer modules.

6. The power generator for a vehicle according to claim 1,
wherein the flow channel is an inner channel of an exhaust pipe of an internal combustion engine mounted on the vehicle, and the fluid is exhaust gas that flows in the exhaust pipe.
